(19) United States
(12) Patent Application Publication
(10) Pub. No.: US 2011/0033982 A1
(43) Pub. Date: Feb. 10, 2011

(54) Lead-forming die and method of manufacturing semiconductor device utilizing lead-forming die

(75) Inventor: Takeshi Kimura, Kumamoto (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki-shi (JP)

(21) Appl. No.: 12/805,368

(22) Filed: Jul. 27, 2010

(30) Foreign Application Priority Data
Aug. 6, 2009 (JP) 2009-183060

(51) Int. Cl. H01L 21/60; H01L 21/48

(52) U.S. Cl. 438/121; 140/105; 257/E21.506

(57) ABSTRACT

Provided is that a lead-forming die includes an upper die and a lower die disposed so as to oppose the upper die; a supporting unit for semiconductor package, provided on an upper face of the lower die; a moving unit provided on a lower face of the upper die and movable in a direction that the upper die and the lower die oppose each other; a plurality of shafts supported by the moving unit so as to axially move with respect thereto; a presser provided above the supporting unit for semiconductor package, and at a lower end portion of the shaft; and a locking device that stops a movement of the shaft, provided between the upper die and the moving unit.

This application is based on Japanese patent application No. 2009-183060, the content of which is incorporated hereinto by reference.

### BACKGROUND

1. Technical Field

The present invention relates to a lead-forming die, and to a method of manufacturing a semiconductor device utilizing the lead-forming die.

2. Related Art

Various proposals are being made on machines and die structure that form an outer lead of a molded semiconductor package such as a QFP package.

For example, JP-A No. H09-97866 proposes utilizing another die, after executing a first lead formation, to press a central portion of the package with a projection so as to correct the shape and adjust coplanarity. JP-A No. H09-252071 proposes setting a package on an exclusive correcting device, after forming leads, and holding the package at different positions according to deformation of the package, so as to correct the shape again and adjust coplanarity. JP-A No. 2001-189409 proposes pressing a protruding portion of a warped package with an elastic material, so as to suppress deformation of the package in the formation process, thus to achieve coplanarity. JP-A No. H06-45493 discloses a technique of correcting a lead that has been formed.

JP-A No. H10-125840 proposes employing a body clamp pin activated by a fluid pressure medium, to thereby stably hold a product to be processed.

The present inventor has recognized as follows. The machines and die structure for forming the outer lead of related art, exemplified by the foregoing patented documents, still cause fluctuation of relative position between the package and the outer lead because of the deformation of the package, upon forming the outer lead of the package, which makes it difficult to attain, through mass production of the packages subjected to the lead formation process, uniform relative position between the package and the outer lead, in the mass-produced packages. Reasons of the deformation of the package include the following.

One is reaction force generated in the lead formation process. In the lead formation process, external force is applied to the outer lead for processing. At this moment, the reaction force in the lead formation process causes the package deformation. Such deformation incurs fluctuation of relative position between the package and the outer lead. The thinner and the larger the package is, the more susceptible to the reaction force in the lead formation process the package becomes, and the more prominent the package deformation becomes.

Another reason is difference in shape among the packages, in the lead formation process. Through the manufacturing process such as complication of internal structure of the package, increase in size and reduction in thickness of the package, and development and application of various molding resins, the package is subjected to thermal history. Accordingly, each package assumes a different shape and warp pattern, despite having been manufactured through the same process. Holding units of package or lead in the machines of related art are not designed for such difference in package shape, and hence have a potential drawback that unintended correction effect may cause deformation of the package through the process, which results in fluctuation of relative position between the package and the outer lead.

In the case of the technique according to JP-A No. H10-125840, the pressure of the upper die clamp pin and the lower die clamp pin is supposed to be equivalent so as to establish a balance, when holding the package in position. Otherwise, the package is shifted to either direction, and thus the predetermined relative position with respect to the die changes. Once the reaction force is applied in the lead formation process under such state, the balance between the upward force and downward force collapses and eventually the package is deformed, resulting in degradation of coplanarity.

The package holding devices according to JP-A No. H09-97866, JP-A No. H09-252071, and JP-A No. 2001-189409 have to be formed according to the warp and shape of the package. Therefore, in the case where the warp and shape of each package are different as described above, the holding devices according to those patented documents are unable to effectively cope with such fluctuation in shape, and prone to incur deformation of the packages while holding them, thus failing in securing coplanarity. Also, JP-A No. H06-45493 proposes changing a position of a holding block according to an IC to undergo the lead correction, and is hence applicable only in the case where the package shape is uniform. Therefore, the holding device according to JP-A No. H06-45493 is not applicable in the case where the packages manufactured through the same process each present a different shape.

Thus, the package holding mechanisms of related art exemplified by the patented documents are unable to effectively cope with the package deformation occurring from the foregoing two reasons, and therefore it is difficult to attain, through mass production of the packages subjected to the lead formation process, uniform relative position between the package and the outer lead, in the mass-produced packages.

### SUMMARY

In one embodiment, there is provided a lead-forming die for a semiconductor package, including an upper die and a lower die disposed so as to oppose the upper die, including:

a supporting unit for semiconductor package, provided on an upper face of the lower die;

a moving unit provided on a lower face of the upper die and movable in a direction that the upper die and the lower die oppose each other;

a plurality of shafts supported by the moving unit so as to axially move with respect thereto;

a presser provided at a lower end portion of the shaft, and above the supporting unit; and

a locking device that stops a movement of the shaft, and is located between the upper die and the moving unit;

wherein the locking device stops the movement of the shaft to thereby fix a position of the presser with respect to the moving unit, while the upper die is moving toward the upper face of the lower die and after the moving unit stops moving by contact with the lower die.

In another embodiment, there is provided a method of manufacturing a semiconductor device, including utilizing the foregoing lead-forming die, thereby forming an outer lead of a semiconductor package having the outer lead.

Since the plurality of shafts is movable in the axial direction, the shafts can remain located so as to follow the profile of the upper surface of the semiconductor package placed on the supporting unit, until the shafts are fixed. Then the locking device stops the movement of the shaft to thereby fix the position of the presser with respect to the moving unit, while the upper die is moving toward the upper face of the lower die and after the moving unit stops moving by contact with the lower die. In this way, the presser is fixed without imposing a load to the semiconductor package. Therefore, deformation of the semiconductor package can be suppressed, and hence fluctuation of the relative position between the package and the outer lead can be suppressed in the lead formation process.

Thus, the present invention enables attaining uniform relative position between the package and the outer lead, upon executing mass production of the package subjected to the lead-forming process.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view showing a structure of a die according to an embodiment of the present invention;

FIG. 2 is a cross-sectional view showing a structure of a locking mechanism according to the embodiment of the present invention;

FIG. 3 is a cross-sectional view of the locking mechanism in a locking position, according to the embodiment of the present invention;

FIG. 4 is an enlarged cross-sectional view of the locking mechanism shown in FIG. 3;

FIGS. 5A and 5B are front views showing the locking mechanism working in a lead forming process according to the embodiment of the present invention;

FIG. 6 is a cross-sectional view showing a structure of a locking mechanism according to a modification of the embodiment of the present invention;

FIG. 7 is a cross-sectional view showing a structure of a locking mechanism according to another modification of the embodiment of the present invention;

FIG. 8 is a cross-sectional view showing a structure of a locking mechanism according to still another modification of the embodiment of the present invention; and

FIGS. 9A and 9B are front views for explaining a drawback of a die of related art.

### DETAILED DESCRIPTION

Before describing of the present invention, the prior art will be explained in detail with reference to FIGS. 9A and 9B in order to facilitate the understanding of the present invention.

In the large-sized package and thin package which are now widely employed, elastic deformation may occur because of the reaction force applied in the lead formation process. Such case is shown in FIGS. 9A and 9B. In the case, for example, where the holding device is located at a central portion of the package, the package is subjected to upward reaction force generated in the lead formation process. In a region where the holding device is not present, the lead formation is executed while elastic deformation 121 takes place (FIG. 9A). Accordingly, when the package is released after the lead formation, the relative position between the package and the outer lead changes, such that coplanarity 122 is degraded to the extent corresponding to the elastic deformation 121 (FIG. 9B).

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

An embodiment of the present invention will be described hereunder, referring to the drawings. In this embodiment, same constituents will be given the same designation, and detailed description thereof will not be repeated.

In this embodiment, also, a back and forth, left and right, and upper and lower direction are specified based on the drawings. Such directions are, however, referred to only for the sake of explicitness in explaining the relative position between the constituents, and not intended for limiting the directions in the manufacturing process or in use of the products embodying the present invention.

Further, in the case where a vertical direction is set as reference, an upward and downward direction, opposing direction and axial direction hereunder referred to are to be construed as generally parallel to the vertical direction. However, this is not for the purpose of limitation.

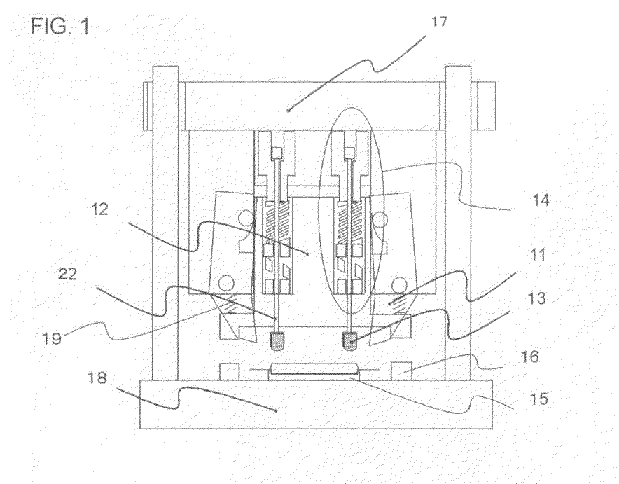

FIG. 1 illustrates a structure of a lead-forming die according to this embodiment.

The lead-forming die according to this embodiment is to be used for a semiconductor package with an outer lead. The lead-forming die includes a holding mechanism that holds the semiconductor package without imposing a load thereto.

Also, the lead-forming die according to this embodiment includes an upper die 17, a lower die 18 located so as to oppose the upper die 17, a base die 15 (base for semiconductor package) provided on the upper face of the lower die 18, a cam 12 (moving unit) provided on the lower face of the upper die 17 and movable in a opposing direction that the upper die 17 and the lower die 18 oppose each other, a plurality of shafts 22 supported by the cam 12 so as to axially move with respect thereto, a profile pin 13 (presser) provided above the base die 15 (base for semiconductor package) and at a lower end portion of the shaft 22, and a locking mechanism 14 (locking device) provided between the upper die 17 and the cam 12, so as to stop the movement of the shaft 22.

The locking mechanism 14 (locking device) according to this embodiment stops the movement of the shaft 22 to thereby fix the position of the profile pin 13 with respect to the cam 12, while the upper die 17 is moving toward the upper face of the lower die 18 and after the cam 12 is stopped by contact with the lower die 18, more particularly the cam stopper 16 provided on the upper face of the lower die 18. In other words the locking mechanism (locking device) according to this embodiment dose not stop the movement of the shaft 22, in first state that distance between upper die 17 and the cam 12 is the maximal length, and the locking mechanism 14 (locking device) according to this embodiment dose not stop the movement of the shaft 22 to thereby fix the position of the profile pin 13 with respect to the cam 12, in second state that distance between upper die 17 and the cam 12 is predetermined length smaller than the maximal length.

Also, as shown in FIG. 1, the lead-forming die according to this embodiment further includes a punch 11 (bending unit) that forms the lead of the semiconductor package.

Description will now be given on the holding mechanism for the semiconductor package according to this embodiment.

As shown in FIG. 1, the dies (upper die 17 and lower die 18) according to this embodiment include therebetween the holding mechanism that holds the package. The holding mechanism includes the base die 15, the cam 12, the plurality of shafts 22, the profile pin 13 and the locking mechanism 14.

The base die 15 serves to sustain the semiconductor package from below. As shown in FIG. 1, the base die 15 is provided on the upper face of the lower die 18. In this embodiment, the base die 15 supports the outer lead in the vicinity of the semiconductor package, from below.

The cam 12 is provided on the lower face of the upper die 17 (face opposing the lower die 18). The cam 12 moves together with the upper die 17, in the opposing direction of the upper die 17 and the lower die 18 (hereinafter simply “opposing direction” as the case may be). When the upper die 17 moves down toward the lower die 18, the cam 12 also moves downward together with the upper die 17. Then the cam 12 enters into contact with the cam stopper 16 (that is a portion of the lower die 18), and is thereby stopped. At this stage, a spring 19 (elastic member) is provided between the upper die 17 and the cam 12, and hence the upper die 17 can move further down toward the lower die 18, even after the cam 12 is stopped.

The cam 12 is stopped at a predetermined position. The position where the cam 12 is stopped may be determined by adjusting the position where the cam 12 enters into contact with the cam stopper 16. Increasing the height of the cam stopper 16 from the upper face of the lower die 18 elevates the position where the cam 12 enters into contact with the cam stopper 16, in other words the stop position becomes closer to the upper die 17 along the opposing direction.

The cam stopper 16 is located around the base die 15 which serves to sustain the semiconductor package from below. The height of the cam stopper 16 is not specifically limited, unless the cam 12 can contact the semiconductor package placed on the base die 15. In this embodiment, thus, the base die 15, the semiconductor package on the base die 15, and the profile pin 13 above the semiconductor package are located in a space defined when the cam 12 enters into contact with the cam stopper 16.

As shown in FIG. 1, the cam 12 includes plurality of recessed portion. On the bottom portion of the recessed portion, an insertion hole is provided for inserting the shaft 22 therethrough. At the lower end portion of the shaft 22, the profile pin 13 (presser) that holds the upper surface of the semiconductor package is provided. On the upper end portion of the shaft 22, a cap is provided so as to prevent the shaft 22 from falling off from the insertion hole. Each of the plurality of shafts 22 is thus supported inside the recessed portion (inner region of the cam 12), so as to move in an axial direction. It is to be noted that hereinafter the profile pin 13 may also refer to the overall structure including the shaft 22 and the presser at the end portion thereof.

The number of profile pins 13 is not specifically limited, as long as two or more are provided. In this embodiment, the plurality of profile pins 13 presses the upper surface of the semiconductor package at two or more positions. Accordingly, the upper surface of the semiconductor package is held over a plane, not at a point.

In this embodiment, the profile pins 13 may be point-symmetrically located, when viewed in the opposing direction, about the center of the upper surface of the semiconductor package placed on the base die 15. Such configuration suppresses emergence of local stress on the semiconductor package. Examples of the location include equilateral triangle, square, regular pentagon, and regular hexagon, in the opposing direction view. Such distribution makes the pressed area per profile pin 13 on the upper surface of the semiconductor package generally uniform, thereby suppressing emergence of local stress.

It is preferable to locate the profile pin 13 (presser) close to a connection point between the semiconductor package and the lead, from the viewpoint of blocking the reaction force generated in the lead formation process. Also it is preferable to provide a greater number of profile pins 13, so as to more effectively follow the profile of the upper surface of the semiconductor package.

In this embodiment, for example, three profile pins 13 may be provided per side (end—center—the other end) of the package, in view of the actual warp state of the package, such that the profile pin 13 at a corner is shared by adjacent two sides and thus the total number of profile pins 13 becomes eight.

The diameter of the presser orthogonal to the axial center is not specifically limited, but may be made larger than that of the shaft 22.

It is preferable to form the tip portion of the presser in a spherical shape, because the contact angle varies depending on the shape of the package, but the presser may be formed in a different shape. Also, the lower end portion of the shaft 22 may be formed in a spherical shape instead of attaching the separately formed profile pin 13.

The presser may be constituted of a metal or an elastic material. The presser may be constituted of a popular iron-based alloy, since only the small self weight of the profile pin 13 is imposed on the package.

Operation of the holding mechanism according to this embodiment will be described hereunder.

A press machine is employed to press the die (upper die 17) upward and downward (in the opposing direction). The upper die 17 relatively moves downward (in the opposing direction) to the lower die 18. In unison with the downward movement of the upper die 17, the cam 12 also moves downward. At the same time, the profile pin 13 inserted through the cam 12, which is axially movable up and downward, also moves downward. Then the tip portion of the profile pin 13 enters into contact with the upper surface of the package placed on the base die 15. The plurality of profile pins 13 is positioned so as to follow the profile of the upper surface of the package. The upper die 17 still keeps descending, however the locking mechanism 14 is not yet activated (in other words, the locking mechanism 14 has not yet rocked the shaft 22, and the profile pin 13 is still axially movable up and downward), and hence the profile pin 13 can freely follow the profile of the upper surface of the package. At this moment, the profile pin 13 does not impose a load (except for the self weight thereof) to the package, unlike in the conventional holding mechanism.

In the case of employing the elastic member of the conventional holding device for the package, a greater load is imposed on the upper surface of the package as the holding device comes closer to the package, because of the restitutive force of the elastic member. Also, in the case where the holding device does not fit the profile of the upper surface of the package, a load is imposed on the upper surface of the package, owing to an unintended correcting effect incurred when the package is held.

In contrast, the profile pin 13 according to this embodiment can freely follow the profile of the upper surface of the package. This is because the plurality of profile pins 13, which is freely movable up and downward, enters into contact with the upper surface of the package while the locking mechanism 14 has not yet been activated. Such structure protects the package from the additional load imposed by the conventional mechanism.

When the upper die 17 moves further downward, the cam 12 provided on the upper die 17 is butted to the cam stopper 16. After such contact, the locking mechanism 14 is activated. Once the locking mechanism 14 is activated, the profile pin 13 is locked at the position defined by the profile of the upper surface of the package. Thus the relative position between the profile pin 13 and the package is fixed. At the same time, the position of the cam 12 and that of the profile pin 13 are fixed. At this moment either, the profile pin 13 does not impose the additional load on the package. In this embodiment, the package is held by the profile pin 13 (presser) fixed in position by the locking mechanism 14.

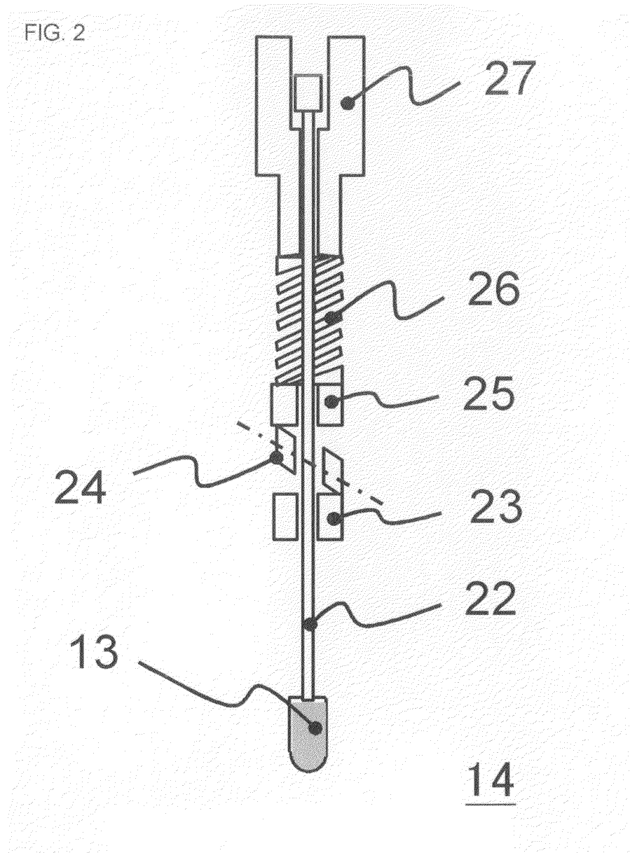

Hereunder, the locking mechanism according to this embodiment will be described. FIG. 2 schematically depicts a structure of the locking mechanism.

As shown in FIG. 2, the locking mechanism 14 (locking device) according to this embodiment includes a clamper 24 and a pinching unit (first pinching unit and second pinching unit) that pinches therebetween the clamper 24 in the axial direction, after the cam 12 (moving unit) is stopped. The clamper 24 includes a through hole for the shaft 22 to pass therethrough, and becomes tilted with respect to the axial direction to thereby press the shaft 22 with the edge of the through hole, upon being pinched by the pinching unit in the axial direction. Such pressing action stops the up or downward movement of the shaft 22.

Between the upper die 17 and the recessed portion of the cam 12, the first pinching unit and the second pinching unit are provided along the axial direction of the shaft 22, with the clamper 24 located therebetween. When the upper die 17 comes closer to the cam 12, the first pinching unit presses the clamper 24 from above, and the second pinching unit from below. Thus, the pinching unit holds the clamper 24 therebetween in the axial direction.

In this embodiment, the first pinching unit is constituted of a cylindrical first washer 25, a spring 26 and a cylindrical push-pin 27. The second pinching unit is constituted of a cylindrical second washer 23. The shaft 22 runs through the push-pin 27, the spring 26, the first washer 25, the clamper 24, and the second washer 23 in a form of a skewer.

The clamper 24 is of a cylindrical shape with the upper face and the lower face inclined with respect to the axial direction. In this embodiment, the upper face and the lower face are generally parallel. The cross-sectional shape of the clamper 24 is, for example, a parallelogram when taken along the axial direction, and circular when taken orthogonally to the axial direction.

The cross-sectional shape of the first washer 25 and the second washer 23 is, for example, rectangular or square when taken along the axial direction.

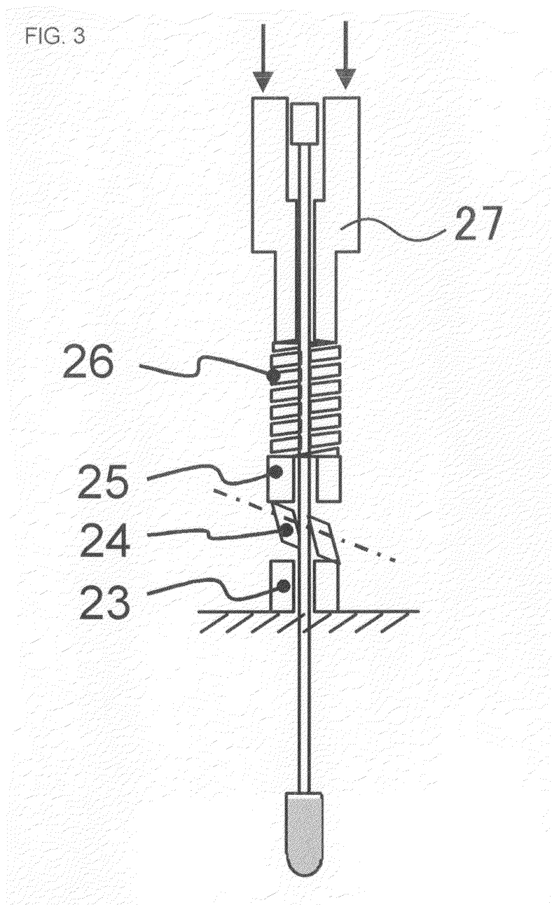

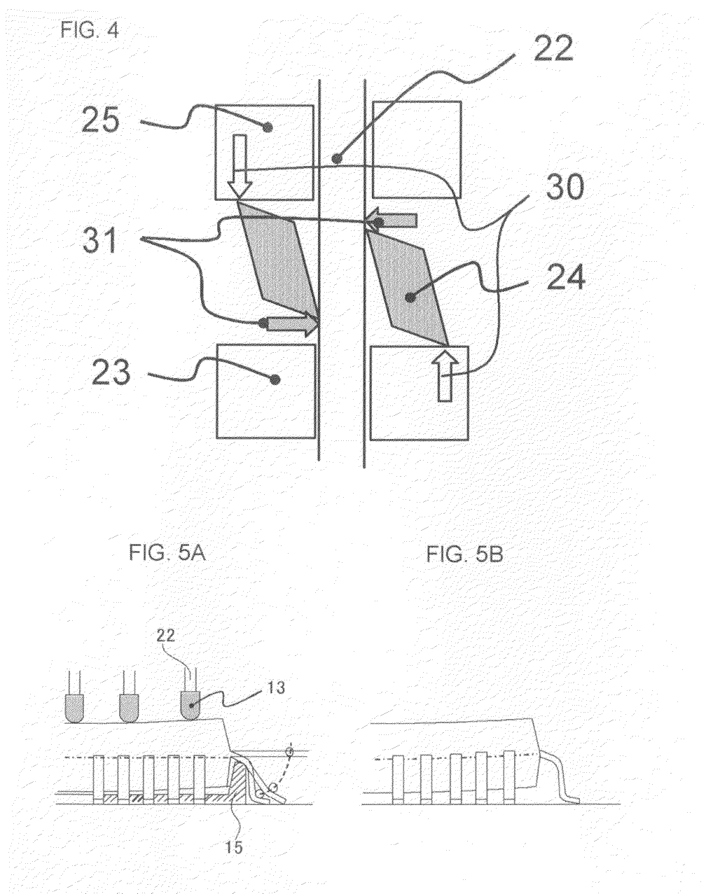

The locking mechanism 14 according to this embodiment works as follows. FIG. 3 illustrates the locking mechanism 14 in a locking position. FIG. 4 is an enlarged drawing focusing on a portion around the clamper 24 shown in FIG. 3.

As stated earlier, the cam 12 gets engaged with the cam stopper 16 and stops at a predetermined position. At this moment, the second washer 23 located on the cam 12 also stops moving and the position of the second washer 23 is fixed. As the upper die 17 moves further downward (so as to come closer to the cam 12), the push-pin 27 is pressed downward by the upper die 17. The push-pin 27 presses the first washer 25 downward via the spring 26. Thus the first washer 25 and the second washer 23 come closer to each other as shown in FIG. 3, such that the lower face of the first washer 25 and the upper face of the second washer 23 hold and press the clamper 24 therebetween. At this moment, as shown in FIG. 4, rotational force 30 is applied to the clamper 24 so as to rotate about the contact point with the second washer 23 and with the first washer 25 as the fulcrum. Accordingly the clamper 24 is tilted with respect to the axial direction, and thereby presses the shaft 22 with the edge of the through hole. To be more detailed, the upper and lower edge of the through hole of the clamper 24 each exert pressing force 31 against the shaft 22, and thereby fix the shaft 22 from both sides. Then as the upper die 17 moves still further downward, the first washer 25 and the second washer 23 are subjected to greater force biasing them to get closer to each other in the axial direction, and hence the force 31 becomes greater. Thus, the shaft 22 is subjected to rotational force by the pressing force 31 exerted thereto from opposite directions, to be thereby pressed against the inner edge of the through hole of the clamper 24, and fixed. Consequently, the position of the profile pin 13, initially movable up and down in the axial direction and positioned according to the profile of the upper surface of the semiconductor package, is fixed with respect to the cam 12, once the locking mechanism 14 is activated. As a result, the locking mechanism 14 serves to fix the profile pin 13 at the position defined by the profile of the upper surface of the semiconductor package, without imposing a load thereto.

The timing for locking the profile pin 13 (timing that the locking mechanism 14 is activated) may be controlled by adjusting, for example, the distance between a lowermost point of the second washer 23 and an uppermost point of the push-pin 27, and the depth of the recessed portion in the opposing direction, between the upper die 17 and the cam 12 in which the locking mechanism 14 is accommodated.

Also, in the lead formation process, the upward reaction force is applied to the package. Accordingly, in order to suppress deformation of the package, the position of the profile pin 13 with respect to the cam 12 is fixed so as to follow the profile of the upper surface of the package, such that the profile pin 13 does not move upward, despite that the reaction force is applied. The timing that the force 31, which serves to fix the position of the profile pin 13, is generated may be controlled according to the timing of lead formation, for example by adjusting the spring 26 and the angle of the sloped surface of the clamper 24.

Further, as shown in FIG. 1, the lead-forming die according to this embodiment includes the punch 11 (bending unit) that bends the outer lead, located on a lateral portion of the cam 12. The base die 15 (base for semiconductor package) sustains the outer lead from below in the vicinity of the semiconductor package.

The punch 11 bends the outer lead while the shaft 22 is locked (the movement of the shaft 22 is stopped) by the locking mechanism 14 (locking device). In other words, the lead formation according to this embodiment is executed when the profile pin 13 is fixed at the position defined by the profile of the upper surface of the semiconductor package, so as not to impose a load thereto. Here, adjusting the length and strength of the spring 19 enables controlling the timing that the locking mechanism 14 is activated and the timing that the punch 11 bends the outer lead.

That is how the lead-forming die according to this embodiment executes the formation of the outer lead of the semiconductor package.

This embodiment offers the following advantageous effects. The holding mechanism in the lead-forming die according to this embodiment employs the locking mechanism 14 to fix the profile pin 13, which is movable up and downward, at the position defined by the profile of the upper surface of the semiconductor package. Such structure allows holding the package without incurring deformation, regardless of the warp and deformation of each of the package. Also, since the plurality of profile pins 13 is provided, the semiconductor package can be exempted from local stress while being held. Accordingly, irrespective of the shape of the package before the lead formation, the package can undergo the formation process as it is, and deformation of the package because of the reaction force applied at the moment of processing can be suppressed. Consequently, elastic deformation of the package because of the reaction force applied at the moment of processing can be suppressed.

FIGS. 5A and 5B schematically depict the locking mechanism according to this embodiment, holding the package. As shown in FIG. 5A, the plurality of profile pins 13 of the locking mechanism 14 according to this embodiment holds the surface of the package and suppresses deformation. Such arrangement allows obtaining an optimal processed shape as shown in FIG. 5B, from a package of a given shape. To be more detailed, the profile pin 13 (presser) provided at the lower end portion of the plurality of shafts 22, which is supported so as to move up and down, is fixed at the position where the presser has first contacted the upper surface of the semiconductor package. Therefore, elastic deformation of the package because of the reaction force applied at the moment of processing can be suppressed. Consequently, fluctuation of relative position between the package and the outer lead can be suppressed. Thus, employing the holding mechanism according to this embodiment allows preventing degradation of coplanarity.

As above, the holding mechanism according to this embodiment suppresses deformation of the semiconductor package, and fluctuation of relative position between the package and the outer lead in the lead formation process. Accordingly, employing the lead-forming die according to this embodiment allows attaining, through mass production of the packages subjected to the lead formation process, uniform relative position between the package and the outer lead, in the mass-produced packages. Thus, the semiconductor package that presents uniform relative position between the package and the outer lead (excellent coplanarity) can be obtained.

The holding mechanism according to this embodiment can hold and fix the package, regardless of how the package is set. The setting form of the package is not specifically limited. For example, either of the package or the outer lead extending from the package may be supported by the base (that is supporting unit). In the case where the package is to be supported at a specific point, a protruding abutment or the like may be provided on the base die 15 at the position corresponding to the supporting point. Although the base is not shown in FIG. 5, when the package is placed on the base die 15 in a natural state the package can be supported by the base at a desired portion. The holding mechanism according to this embodiment can therefore be employed for holding the package for other desired purposes, in addition to the lead formation. For example, there are cases where the package must be fixed without suffering deformation, for a work that requires high precision such as measurement of the package or correction of the lead. In such cases, it is advantageous to employ the holding mechanism that holds the package according to this embodiment.

### Second Embodiment

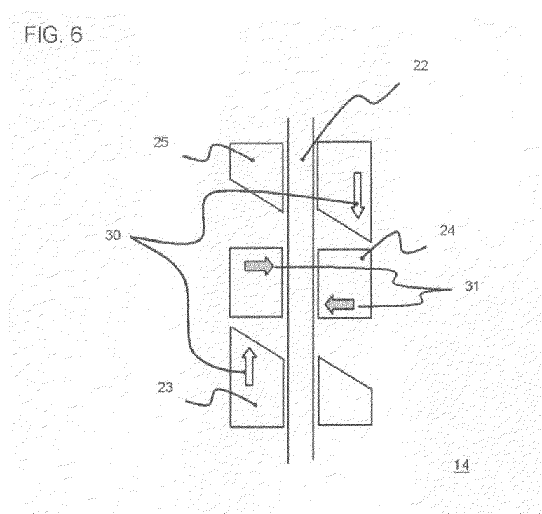

A second embodiment is similar to the first embodiment, except that the locking mechanism 14 has a different structure. More specifically, the first washer 25 and the second washer 23 include a sloped surface with respect to the axial direction, while the clamper 24 does not include a sloped surface. Referring to FIG. 6, differences from the first embodiment will be described in details hereunder.

The locking mechanism 14 (locking device) according to the second embodiment includes the first pinching unit and the second pinching unit located in the axial direction of the shaft 22, on the respective sides of the clamper 24, between the upper die 17 and the recessed portion of the cam 12. When the upper die 17 comes closer to the cam 12, the first pinching unit presses the clamper 24 from above, and the second pinching unit from below. Thus, the pinching unit holds the clamper 24 therebetween in the axial direction. The clamper 24 is tilted with respect to the axial direction upon being pressed in the axial direction, and presses the shaft 22 with the edge of the through hole thereby stopping the up or downward movement of the shaft 22.

In this embodiment, the upper face and the lower face of the cylindrical clamper 24 is generally perpendicular to the axial direction. The cross-sectional shape of the clamper 24 is, for example, rectangular or square when taken in the axial direction.

Also, the lower face of the cylindrical first washer 25 and the upper face of the cylindrical second washer 23 are inclined with respect to the axial direction. In this embodiment, such upper face and such lower face are generally parallel. The cross-sectional shape of the first washer 25 and the second washer 23 is, for example, trapezoidal when taken in the axial direction, and circular when taken orthogonally to the axial direction.

As shown in FIG. 6, the clamper 24 is subjected to rotational force 30 exerted about the contact point with the second washer 23 and with the first washer 25 as the fulcrum. Accordingly, the upper and lower edge of the through hole of the clamper 24 each exert pressing force 31 against the shaft 22 from opposite directions, and thereby fix the shaft 22. Then, as the upper die moves further downward the pressing force 31 is increased. Thus, the shaft 22 is subjected to rotational force by the pressing force 31 exerted thereto from opposite directions, to be thereby pressed against the inner edge of the through hole of the clamper 24, and fixed. As a result, the locking mechanism 14 according to the second embodiment serves to fix the profile pin 13 at the position defined by the profile of the upper surface of the semiconductor package, without imposing a load thereto, and therefore the same advantageous effects as those offered by the first embodiment can be attained.

### Third Embodiment

A third embodiment is similar to the first embodiment, except that the locking mechanism 14 has a different structure. More specifically, while the locking mechanism 14 according to the first embodiment detains the shaft 22 with the rotational force, in the second embodiment the pressing force exerted from both sides is employed to detain the shaft 22.

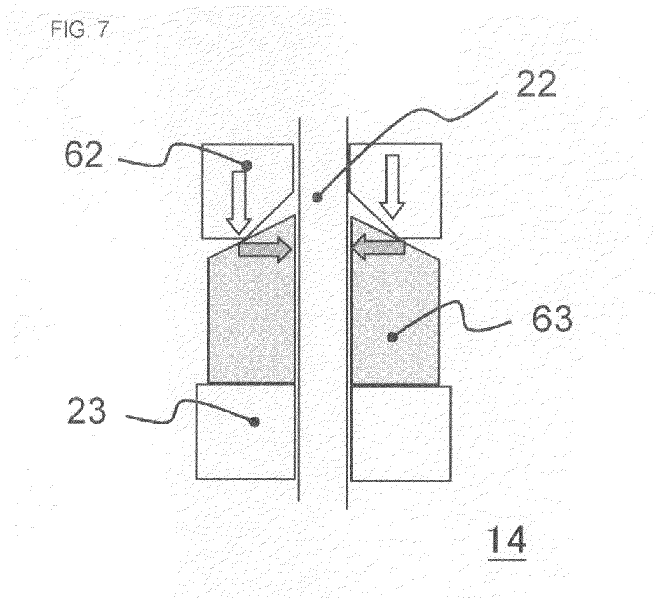

As shown in FIG. 7, the locking mechanism 14 (locking device) includes a clamping member 63 (clamper), and a pinching unit that holds the clamping member 63 in the axial direction after the cam 12 stops. The clamping member 63 includes a through hole for the shaft 22 to pass therethrough. When the clamping member 63 is pressed in the axial direction of the shaft 22 the inner diameter of the through hole is reduced, so that the inner edge of the through hole presses the shaft 22 from both sides. The clamping member 63 stops the movement of the shaft 22, with such pressing force exerted from both sides thereof.

Also, the pinching unit of the locking mechanism 14 is provided between the upper die 17 and the recessed portion of the cam 12, and includes the first pinching unit that presses the clamper 24 from above and the second pinching unit that presses the clamper 24 from below, in axial direction of the shaft 22. The first pinching unit is constituted of the annular member 62, and the second pinching unit is constituted of the second washer 23.

As shown in FIG. 7, when a projection of the annular member 62 is butted to the sloped surface of the clamping member 63 in the axial direction, the clamping member 63 is subjected to stress toward the shaft 22. Accordingly, the inner wall of the through hole of the clamping member 63 is shifted toward the shaft 22. As a result the inner wall of the through hole of the clamping member 63 is pressed against the lateral face of the shaft 22, so that the shaft 22 is rocked (the position of the shaft 22 with respect to the cam 12 is fixed).

In this embodiment, the annular member 62 and the clamping member 63 may oppose via sloped surfaces generally parallel to each other (inclined with respect to the axial direction). For example, the annular member 62 may have a concave surface and the clamping member 63 a convex surface, to be engaged in the axial direction. In this case, the convex surface of the clamping member 63 slides inwardly along the concave surface of the annular member 62, and thus the clamping member 63 incurs stress toward the shaft 22. As a result, the shaft 22 can be fixed by the pressing force of the clamping member 63. Alternatively, the annular member 62 may have a convex surface and the clamping member 63 a concave surface, to be engaged in the axial direction. In this case, it is the annular member 62 that serves to fix the shaft 22.

The clamping member 63 may be constituted of a plurality of elements. The clamping member 63 may be made of an elastic material, though not limited thereto.

The clamping member 63 may also include a sloped surface on the lower face thereof. In this case, for example a projection may be provided on the upper face of the second washer 23, as on the annular member 62. For instance, the stress on the clamping member 63 arising from the contact with the annular member 62 and with the second washer 23 should be both exerted toward the shaft 22. Such configuration allows increasing the pressing force of the clamping member 63 against the shaft 22.

Thus, the locking mechanism 14 according to the third embodiment serves to fix the profile pin 13 at the position defined by the profile of the upper surface of the semiconductor package, without imposing a load thereto, and therefore the same advantageous effects as those offered by the first embodiment can be attained.

### Fourth Embodiment

A fourth embodiment is similar to the first embodiment, except that the locking mechanism 14 has a different structure.

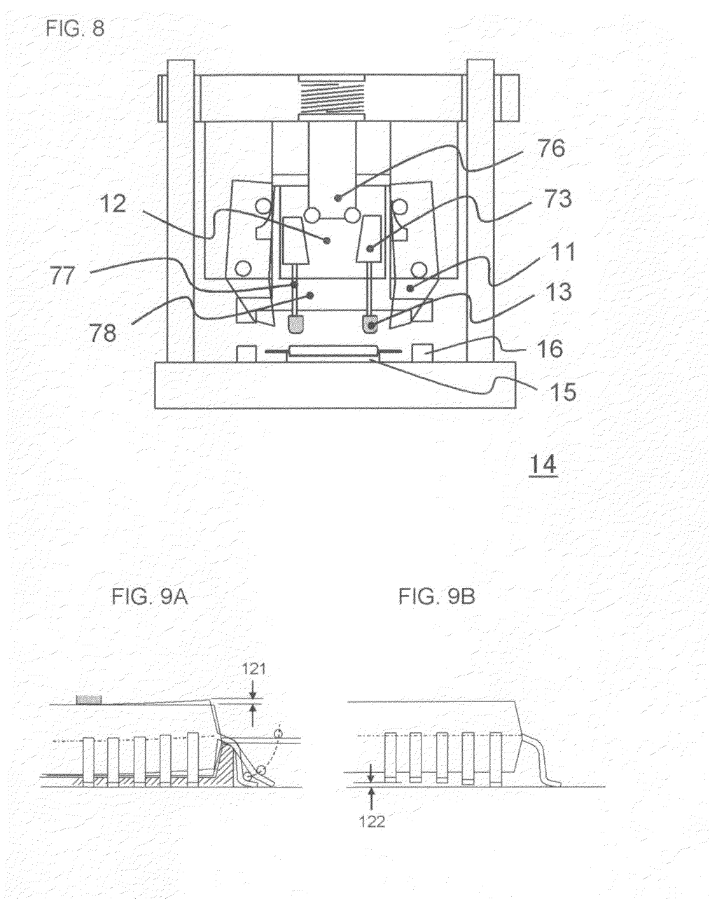

The locking mechanism 14 according to the fourth embodiment will be described hereunder, referring to FIG. 8.

The locking mechanism 14 (locking device) according to the fourth embodiment includes a tapered member 73 provided on the upper end portion of a shaft 77 opposite to the profile pin 13 (presser) and including a sloped surface inclined with respect to the axial direction of the shaft 77, and a pusher 76 (roller unit) movable in unison with the upper die 17 in the opposing direction, to be butted to the sloped surface of the tapered member 73 to thereby squeeze the tapered member 73. In this embodiment, the roller is located at a corner portion of the pusher 76. The roller is to be butted to the sloped surface of the tapered member 73.

The cam 12 (moving unit) includes a through hole for the shaft 77 to pass therethrough. After the cam 12 is stopped, the tapered member 73 provided on the shaft 77 is squeezed by the pusher 76, and thereby the shaft 77 is pressed against the inner wall of the through hole.

As in the first embodiment, the descending movement of the die (upper die 17) is utilized to activate the locking mechanism 14. The descending movement of the upper die 17 brings the pusher 76 into contact with the tapered member 73, thereby exerting a lateral force to the shaft 77. Accordingly, the shaft 77 is pressed against a shaft guide 78, and fixed thereto.

As a result, the locking mechanism 14 according to the fourth embodiment serves to fix the profile pin 13 at the position defined by the profile of the upper surface of the semiconductor package, without imposing a load thereto, and therefore the same advantageous effects as those offered by the first embodiment can be attained.

Naturally, the foregoing embodiments and the plurality of modifications may be combined unless contradiction arises. Although the structure of each part of the foregoing embodiments and the modifications has been specifically described, the structure may be modified in various manners within the scope of the present invention.

It is apparent that the present invention is not limited to the above embodiment, and may be modified and changed without departing from the scope and spirit of the invention.

What is claimed is:

1. A lead-forming die for a semiconductor package, including an upper die and a lower die disposed so as to oppose said upper die, comprising:
a supporting unit for semiconductor package, provided on an upper face of said lower die;
a moving unit provided on a lower face of said upper die and movable in a opposing direction that said upper die and said lower die oppose each other;
a plurality of shafts supported by said moving unit so as to axially move with respect thereto;
a presser provided at a lower end portion of said shaft, and above said supporting unit; and
a locking device that stops a movement of said shaft, and is located between said upper die and said moving unit;
wherein said locking device stops said movement of said shaft to thereby fix a position of said presser with respect to said moving unit, while said upper die is moving toward said upper face of said lower die and after said moving unit stops moving by contact with said lower die.

2. The lead-forming die according to claim 1,
wherein said locking device includes:
a clamper that includes a through hole for said shaft to pass therethrough, and is tilted with respect to an axial direction to thereby press said shaft with an edge of said through hole, upon being pinched in said axial direction; and
a pinching unit that pinches therebetween said clamper in said axial direction.

3. The lead-forming die according to claim 1,
wherein said locking device includes:
a clamper that includes a through hole for said shaft to pass therethrough, an inner diameter of which is reduced so that an inner surface thereof presses said shaft, upon being pinched in said axial direction; and
a pinching unit that pinches therebetween said clamper in said axial direction.

4. The lead-forming die according to claim 1,
wherein said locking device includes:
a tapered member provided on an upper end portion of said shaft opposite to said presser and including a sloped surface inclined with respect to said axial direction of said shaft, and
a roller unit movable in unison with said upper die in said opposing direction; and
said moving unit includes a through hole for said shaft to pass therethrough, and
said roller unit contacts with said sloped surface to thereby push out said tapered member of said shaft so that said shaft is pressed against an inner wall of said through hole.

5. The lead-forming die according to claim 1, wherein a tip portion of said presser is spherical.

6. The lead-forming die according to claim 1, wherein a plurality of said pressers is point-symmetrically located, in a viewed of said opposing direction, about a center of an upper surface of said semiconductor package placed on said supporting unit for semiconductor package.

7. The lead-forming die according to claim 1, further comprising a bending unit that bends said outer lead while said locking device stops said movement of said shaft, and is located on a lateral portion of said moving unit.

8. The lead-forming die according to claim 1, wherein said supporting unit for semiconductor package supports said outer lead from below, in the vicinity of said semiconductor package.

9. A method of manufacturing a semiconductor device, comprising utilizing the lead-forming die according to claim 1, thereby forming an outer lead of a semiconductor package having said outer lead.
